(19) United States
(12) Patent Application Publication
(10) Pub. No.: US 2022/0288738 A1
(43) Pub. Date: Sep. 15, 2022

(54) PROCESSING APPARATUS

(71) Applicant: DISCO CORPORATION, Tokyo (JP)

(72) Inventors: Atsushi TAKAGI, Tokyo (JP); Takafumi OMORI, Tokyo (JP)

(21) Appl. No.: 17/653,568

(22) Filed: Mar. 4, 2022

(30) Foreign Application Priority Data
Mar. 10, 2021 (JP) 2021-038161

(51) Int. Cl. B23Q 15/26; B23Q 3/18; B23Q 3/06; B23Q 17/20; B23Q 17/22; B23Q 17/24

(52) U.S. Cl. CPC B23Q 15/26; B23Q 3/186; B23Q 3/06; B23Q 17/20; B23Q 17/2291; B23Q 17/2414; B23Q 2717/00

(57) ABSTRACT

An imaging unit of a processing apparatus includes a microscope, and an imaging element connected to the microscope and including a plurality of pixels that capture an image. A control unit has a target pattern storage section that stores a target pattern for performing pattern matching, and a rectilinear region detection section that detects a rectilinear region on the basis of an image from the imaging element, calculates a deviation angle between a direction of the rectilinear region detected by the rectilinear region detection section and a processing feeding direction, and adjusts a relative angle between the target pattern stored in the target pattern storage section and a characteristic pattern on a wafer, to perform the pattern matching.

### BACKGROUND OF THE INVENTION

### Field of the Invention

The present invention relates to a processing apparatus for processing a wafer formed on a front surface thereof with a plurality of devices in the state of being partitioned by a plurality of intersecting streets.

### Description of the Related Art

A wafer formed on a front surface thereof with a plurality of devices such as integrated circuits (ICs) and large-scale integration (LSI) circuits in the state of being partitioned by a plurality of intersecting streets is divided into individual device chips by a dicing apparatus or a laser processing apparatus, and the thus divided device chips are utilized for electric apparatuses such as mobile phones and personal computers.

The dicing apparatus includes at least a chuck table that holds a wafer, a cutting unit including, in a rotatable manner, a cutting blade for cutting the wafer held by the chuck table, a processing feeding mechanism that puts the chuck table and the cutting unit into relative processing feeding, an imaging unit that images the wafer held by the chuck table to detect a region to be cut, and a control unit that performs alignment for matching a street of the wafer to a processing feeding direction of the cutting blade on the basis of a signal from the imaging unit, and can divide the wafer with high accuracy (see, for example, Japanese Patent No. 2562936).

In addition, the laser processing apparatus includes a laser processing unit in place of the cutting unit in the dicing apparatus, and, similarly to the dicing apparatus, can process the wafer with high accuracy by performing alignment.

### SUMMARY OF THE INVENTION

In the abovementioned alignment, a characteristic pattern of the device formed on the front surface of the wafer is stored as a target pattern, and, on the basis of an image of the wafer obtained by imaging by the imaging unit, the street is detected by pattern matching between the stored target pattern and the characteristic pattern on the wafer. Therefore, when the direction of the street is largely deviated from the processing feeding direction, the matching degree between the stored target pattern and the characteristic pattern on the wafer is lowered, the same pattern as the stored target pattern cannot be found from the device, and an alignment error would be generated.

To solve this problem, the wafer is held by the chuck table such that the inclination of the street relative to the processing feeding direction is within ±3°, and, while rotating the wafer by 1° at a time on image processing, pattern matching is performed, and alignment is performed by taking a pattern of a highest matching degree as the same pattern as the target pattern.

However, there are problems that the inclination of the street relative to the processing feeding direction should be limited to within ±3°, that a matching degree of 100% cannot be expected, and that there is a time loss.

Accordingly, it is an object of the present invention to provide a processing apparatus capable of achieving a high pattern matching degree.

In accordance with an aspect of the present invention, there is provided a processing apparatus for processing a wafer formed on a front surface thereof with a plurality of devices in a state of being partitioned by a plurality of intersecting streets, the processing apparatus including a chuck table that holds the wafer, a processing unit that processes the wafer held by the chuck table, a processing feeding mechanism that puts the chuck table and the processing unit into relative processing feeding, an imaging unit that images the wafer held by the chuck table to detect a region to be processed, and a control unit, in which the imaging unit includes a microscope and an imaging element connected to the microscope and including a plurality of pixels that capture an image, the control unit has a target pattern storage section that stores a target pattern for performing pattern matching and a rectilinear region detection section that detects a rectilinear region on the basis of an image from the imaging element, and a deviation angle between a direction of the rectilinear region detected by the rectilinear region detection section and the processing feeding direction is calculated, and a relative angle between the target pattern stored in the target pattern storage section and a characteristic pattern on the wafer is adjusted, to perform the pattern matching.

Preferably, the control unit rotates the chuck table by the deviation angle, to adjust the relative angle. Preferably, the control unit rotates the target pattern stored in the target pattern storage section by the deviation angle through image processing to adjust the relative angle.

According to the present invention, there is no limitation that the inclination of the street relative to the processing feeding direction should be set to within a predetermined angle, a matching degree of 100% can be expected, a time loss is reduced, and the abovementioned problem in alignment can be solved.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a processing apparatus of an embodiment of the present invention;

FIG. 2 is an enlarged perspective view of an imaging unit and a wafer depicted in FIG. 1;

FIG. 3A is a schematic view of an image obtained by imaging the wafer in a state in which a deviation angle between a rectilinear region (street) of the wafer depicted in FIG. 2 and a processing feeding direction (X-axis direction) of the processing apparatus depicted in FIG. 1 is θ;

FIG. 3B is a schematic view of an image indicating a state in which the chuck table is rotated by the deviation angle θ from the state depicted in FIG. 3A;

FIG. 4A is a schematic view of a target pattern stored in a target pattern storage section; and

FIG. 4B is a schematic view indicating a state in which the target pattern is rotated by the deviation angle θ from the state depicted in FIG. 4A through image processing.

### DETAILED DESCRIPTION OF THE PREFERRED EMBODIMENT

A processing apparatus of an embodiment of the present invention will be described below referring to the drawings.

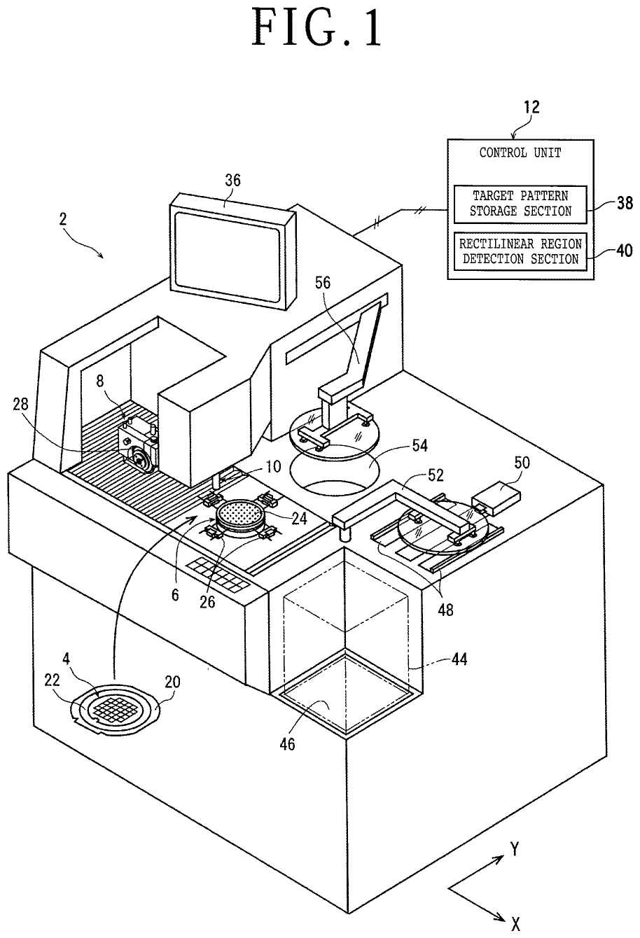

Referring to FIG. 1, the processing apparatus denoted as a whole by a reference sign “2” includes a chuck table 6 that holds a wafer 4, a processing unit 8 that processes the wafer 4 held by the chuck table 6, a processing feeding mechanism (not illustrated) that puts the chuck table 6 and the processing unit 8 into relative processing feeding, an imaging unit 10 that images the wafer 4 held by the chuck table 6 to detect a region to be processed, and a control unit 12.

The wafer 4 to be processed by the processing apparatus 2 is formed, for example, an appropriate semiconductor material such as silicon. On a front surface 4a of the wafer 4, a plurality of streets 14 as rectilinear regions are provided, and the plurality of streets 14 are as a whole combined in a grid pattern. The front surface 4a of the wafer 4 is partitioned into a plurality of rectangular regions by the streets 14 in the grid pattern, and devices 16 such as ICs and LSI circuits are formed in respective ones of the plurality of rectangular regions.

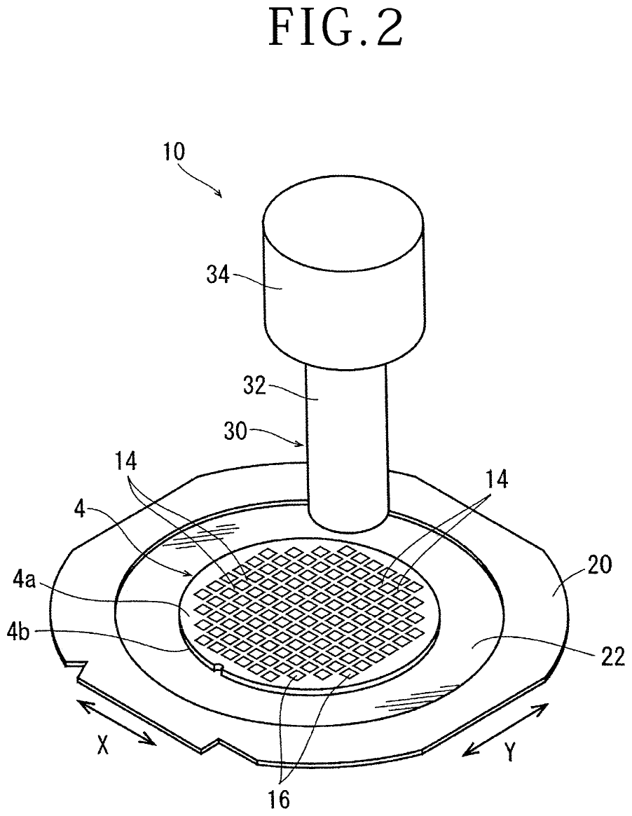

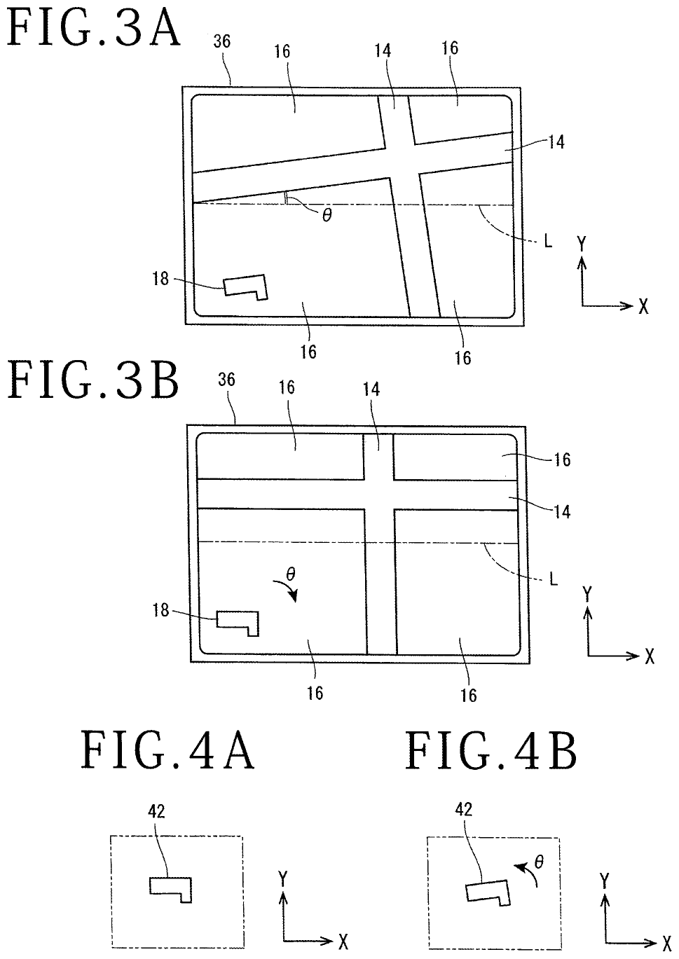

The device 16 has a characteristic pattern used as a target pattern for performing pattern matching at the time of alignment in the processing apparatus 2. The device 16 in the present embodiment has an L-shaped characteristic pattern 18 as depicted in FIG. 3. In addition, as depicted in FIG. 2, a back surface 4b of the wafer 4 is attached to a dicing tape 22 whose peripheral edge is fixed to an annular frame 20, and the wafer 4 is supported by the annular frame 20 through the dicing tape 22.

The chuck table 6 of the processing apparatus 2 is configured so as to be movable in an X-axis direction indicated by the arrow X in FIG. 1 and rotatable around an axis extending in the vertical direction. As depicted in FIG. 1, at an upper end part of the chuck table 6, a porous circular suction chuck 24 connected to suction means (not illustrated) is disposed. The chuck table 6 suction-holds the wafer 4 placed on an upper surface thereof, by generating a suction force at the suction chuck 24 by the suction means. In addition, at the peripheral edge of the chuck table 6, a plurality of clamps 26 are disposed at intervals in the circumferential direction. Note that a Y-axis direction indicated by the arrow Y in FIG. 1 is a direction orthogonal to the X-axis direction, and an XY plane defined by the X-axis direction and the Y-axis direction is substantially horizontal.

The processing apparatus 2 of the present embodiment is a dicing apparatus as an example of the processing apparatus of the present invention, and the processing unit 8 of the present embodiment is configured as a cutting unit that cuts the wafer 4. The processing unit (cutting unit) 8 includes, in a rotatable manner, an annular cutting blade 28 that cuts the wafer 4 suction-held by the chuck table 6. The cutting blade 28 is disposed along the X-axis direction and is configured to be rotatable around an axis extending in the Y-axis direction.

Though not illustrated, the processing feeding mechanism includes an X-axis feeding mechanism that moves the chuck table 6 in the X-axis direction, a Y-axis feeding mechanism that moves the processing unit 8 in the Y-axis direction, and a chuck table motor that rotates the chuck table 6 around an axis extending in the vertical direction. The X-axis feeding mechanism may be configured to have a ball screw connected to the chuck table 6 and extending in the X-axis direction, and a motor that rotates the ball screw. In addition, the Y-axis feeding mechanism may be configured to have a ball screw connected to the processing unit 8 and extending in the Y-axis direction, and a motor that rotates the ball screw. In the processing feeding mechanism, the chuck table 6 and the processing unit 8 are put into relative processing feeding in both the X-axis direction and the Y-axis direction, and the chuck table 6 is rotated.

As depicted in FIG. 2, the imaging unit 10 includes a microscope 30, and an imaging element (not illustrated) that includes a plurality of pixels connected to the microscope 30 and capturing an image. The microscope 30 has a cylindrical microscope housing 32, and a lens (not illustrated) accommodated in the microscope housing 32. An imaging element housing 34 is connected to an upper end of the microscope housing 32, and the imaging element is accommodated in the inside of the imaging element housing 34. In the imaging unit 10, light incident on the microscope 30 is converted into an electrical signal of image data by the imaging element, and the electrical signal is outputted to the control unit 12. In addition, the image obtained by imaging by the imaging unit 10 is displayed on a monitor 36 (see FIG. 1).

On the monitor 36, a center line L (see FIG. 3) indicating the X-axis direction that is a processing feeding direction is displayed, in addition to the image obtained by imaging by the imaging unit 10. The center line L is formed in a visual field of the imaging unit 10, and is displayed along a transverse direction at the center in the longitudinal direction of the monitor 36.

Though not illustrated, the control unit 12 configured by a computer includes a central processing unit (CPU) that performs arithmetic processing according to a control program, a read only memory (ROM) that stores the control program and the like, and a readable-writable random access memory (RAM) that stores calculation results and the like, and controls operation of the processing apparatus 2.

As depicted in FIG. 1, the control unit 12 includes a target pattern storage section 38 that stores a target pattern for performing pattern matching, and a rectilinear region detection section 40 that detects a rectilinear region on the basis of an image from the imaging element of the imaging unit 10. The target pattern storage section 38 of the present embodiment stores a target pattern 42 (see FIG. 4) of the same shape as the characteristic pattern 18 provided on the device 16 of the wafer 4.

The orientation of the target pattern 42 stored in the target pattern storage section 38 is the same as the orientation of the characteristic pattern 18 on the wafer 4 at the time when the street 14 of the wafer 4 is matched to the X-axis direction (processing feeding direction) of the processing apparatus 2. In other words, when the street 14 of the wafer 4 is matched to the X-axis direction, a relative angle between the target pattern 42 and the characteristic pattern 18 on the wafer 4 becomes 0°, and the target pattern 42 and the characteristic pattern 18 are accurately overlapped (coincide) with each other. Note that the target pattern storage section 38 can store an optional pattern as the target pattern.

The rectilinear region detection section 40 of the control unit 12 detects the street 14 which is a rectilinear region on the front surface 4a of the wafer 4, on the basis of the image obtained by imaging by the imaging unit 10. Note that the rectilinear region detection section 40 may be one that detects a straight line by the known Hough transform.

The control unit 12 has the X-axis direction and the Y-axis direction preliminarily inputted thereto, and the control unit 12 calculates a deviation angle θ (see FIG. 3A) between the direction of the rectilinear region (street 14) detected by the rectilinear region detection section 40 and the processing feeding direction (the X-axis direction in the present embodiment). Further, the control unit 12 adjusts the relative angle between the target pattern 42 stored in the target pattern storage section 38 and the characteristic pattern 18 on the wafer 4, on the basis of the calculated deviation angle θ.

As depicted in FIG. 1, the processing apparatus 2 of the present embodiment further includes a cassette base 46 on which a cassette 44 accommodating a plurality of wafers 4 is placed and which is liftable upward and downward, a conveying-in/conveying-out mechanism 50 which draws out the wafer 4 before processing from the cassette 44, conveys the wafer 4 to a temporary placing table 48, and conveys in the processed wafer 4 positioned on the temporary placing table 48 to the cassette 44, a first conveying mechanism 52 that conveys the wafer 4 before processing, which has been conveyed from the cassette 44 to the temporary placing table 48, to the chuck table 6, a cleaning unit 54 that cleans the processed wafer 4, and a second conveying mechanism 56 that conveys the processed wafer 4 from the chuck table 6 to the cleaning unit 54.

At the time of cutting the wafer 4 by use of the processing apparatus 2 abovementioned, first, the wafer 4 before processing is drawn out from the cassette 44 to the temporary placing table 48 by the conveying-in/conveying-out mechanism 50, thereafter the wafer 4 is conveyed from the temporary placing table 48 to the chuck table 6 by the first conveying mechanism 52, and the wafer 4 is placed on an upper surface of the chuck table 6 with the front surface 4a directed upward.

At the time of placing the wafer 4 on the chuck table 6, the direction of the street 14 is preferably aligned to the X-axis direction as much as possible; however, in the processing apparatus 2 of the present embodiment, there is no limitation that “the inclination of the street 14 relative to the X-axis direction should be set within a predetermined angle.” After the wafer 4 is placed on the chuck table 6, the wafer 4 is suction-held by the chuck table 6, and the annular frame 20 is fixed by the plurality of clamps 26.

Next, the street 14 of the wafer 4 as a region to be cut is detected, the street 14 is aligned with the X-axis direction which is the processing feeding direction of the cutting blade 28, and alignment for adjusting the positional relationship between the street 14 and the cutting blade 28 is performed.

In the alignment, first, the chuck table 6 is moved by the X-axis feeding mechanism, and the wafer 4 is positioned under the imaging unit 10. Next, the wafer 4 is imaged by the imaging unit 10, and the image obtained by the imaging is outputted from the imaging unit 10 to the control unit 12. Then, in the control unit 12, the street 14 as a rectilinear region on the front surface 4a of the wafer 4 is detected by the rectilinear region detection section 40, on the basis of the image of the wafer 4 imaged by the imaging unit 10. In addition, the control unit 12 calculates the deviation angle θ (see FIG. 3A) between the direction of the street 14 detected by the rectilinear region detection section 40 and the X-axis direction.

In a case where the deviation angle θ is not 0°, the control unit 12 adjusts the relative angle between the target pattern 42 stored in the target pattern storage section 38 and the characteristic pattern 18 on the wafer 4, on the basis of the calculated deviation angle θ.

Specifically, the control unit 12 operates the chuck table motor to rotate the chuck table 6 suction-holding the wafer 4 by the deviation angle θ. As a result, as depicted in FIG. 3B, the direction of the street 14 of the wafer 4 and the X-axis direction are matched to each other. In addition, the relative angle between the target pattern 42 (see FIG. 4A) stored in the target pattern storage section 38 and the characteristic pattern 18 (see FIG. 3B) on the wafer 4 becomes 0°, and the target pattern 42 and the characteristic pattern 18 are overlapped with each other.

At the time of adjusting the relative angle between the target pattern 42 and the characteristic pattern 18, the wafer 4 having the characteristic pattern 18 may be rotated as abovementioned, but, on the contrary, the target pattern 42 stored in the target pattern storage section 38 may be rotated by image processing. For example, the target pattern 42 stored in the state depicted in FIG. 4A is rotated by the deviation angle θ by image processing as depicted in FIG. 4B. As a result, in a case where the street 14 of the wafer 4 is deviated from the X-axis direction by the deviation angle 19, data of the target pattern 42 stored in the target pattern storage section 38 is modified such that the target pattern 42 (see FIG. 4B) and the characteristic pattern 18 (see FIG. 3A) on the wafer 4 are overlapped with each other.

After the relative angle between the target pattern 42 and the characteristic pattern 18 on the wafer 4 is adjusted, while the chuck table 6 and the imaging unit 10 are relatively moved in the X-axis direction or the Y-axis direction by the processing feeding mechanism, a plurality of regions of the wafer 4 are imaged, and the characteristic pattern 18 is extracted by pattern matching. In this instance, the control unit 12 calculates a matching degree of the respective ones of a plurality of images obtained by imaging with the target pattern 42.

In the present embodiment, as abovementioned, the relative angle between the target pattern 42 stored in the target pattern storage section 38 and the characteristic pattern 18 on the wafer 4 is adjusted to 0°, so that the matching degree of the image including the characteristic pattern 18 can be 100%. Then, on the basis of the characteristic pattern 18 extracted by pattern matching, position information concerning the street 14 which is a region to be cut is acquired. Since the positional relationship between the characteristic pattern 18 on the wafer 4 and the street 14 is preliminarily inputted into the control unit 12, the position information concerning the street 14 can be acquired by extracting the characteristic pattern 18. In addition, in a case where the relative angle between the target pattern 42 and the characteristic pattern 18 is adjusted by rotating the target pattern 42 by image processing, the chuck table 6 is rotated by the deviation angle θ, and the street 14 is matched to the X-axis direction.

However, strictly speaking, even if the chuck table 6 is rotated by an amount of the calculated deviation angle θ, a slight deviation between the street 14 and the X-axis direction may be left. Therefore, it is desirable to extract the characteristic patterns 18 at two spaced parts by pattern matching, and further to finely adjust the angle of the wafer 4 with high accuracy, and to match the street 14 to the X-axis direction.

Next, the chuck table 6 is moved, and the cutting blade 28 is positioned on an upper side of the street 14 matched to the X-axis direction. Subsequently, the processing unit 8 is lowered, a cutting edge of the cutting blade 28 rotated at high speed is made to cut into the wafer 4, specifically into the street 14 matched to the X-axis direction, and, while supplying cutting water to the part where the cutting edge of the cutting blade 28 is made to cut in, the chuck table 6 is put to processing feeding in the X-axis direction relative to the processing unit 8, thereby performing cutting for forming a cut groove along the street 14. Next, while the processing unit 8 is subjected to indexing feeding in the Y-axis direction relative to the chuck table 6, by an amount of the interval of the streets 14 in the Y-axis direction, cutting is repeated, to form cut grooves at all the streets 14 matched to the X-axis direction.

Subsequently, the chuck table 6 is rotated 90°, and the street 14 in a second direction orthogonal to the streets 14 in a first direction previously formed with the cut grooves is matched to the X-axis direction. Then, cutting and indexing feeding are repeated to form cut grooves in a grid pattern along all the streets 14. Next, after cutting is conducted, the wafer 4 is conveyed from the chuck table 6 to the cleaning unit 54 by the second conveying mechanism 56, and the wafer 4 is cleaned by the cleaning unit 54. Then, the wafer 4 is conveyed from the cleaning unit 54 to the temporary placing table 48 by the first conveying mechanism 52, and the wafer 4 is conveyed out from the temporary placing table 48 to the cassette 44 by the conveying-in/conveying-out mechanism 50.

As abovementioned, in the processing apparatus 2 of the present embodiment, after the wafer 4 is placed on the chuck table 6, the relative angle between the target pattern 42 stored in the target pattern storage section 38 and the characteristic pattern on the wafer 4 is adjusted such that the target pattern 42 and the characteristic pattern 18 are accurately overlapped with each other, and, therefore, it is unnecessary to set the inclination of the street 14 relative to the X-axis direction to within a predetermined angle, at the time of placing the wafer 4 on the chuck table 6.

In addition, in the present embodiment, since the relative angle between the target pattern 42 and the characteristic pattern 18 is adjusted such that the target pattern 42 and the characteristic pattern 18 are accurately overlapped with each other, a matching degree of 100% can be expected between the target pattern 42 and the characteristic pattern 18 in pattern matching.

Further, in the present embodiment, after the relative angle between the target pattern 42 and the characteristic pattern 18 is adjusted, the wafer 4 is imaged before performing pattern matching, and, therefore, the pattern matching can be completed in a short time. In other words, it is unnecessary to repeat pattern matching while rotating the wafer 4 by 1° at a time on image processing (while finely adjusting the angle of the wafer 4), and time loss is reduced. Thus, in the present embodiment, the conventional problem in alignment can be solved.

Note that, in the present embodiment, an example in which the processing apparatus 2 is configured as a dicing apparatus that cuts the wafer 4 has been described, but, the processing apparatus of the present invention may be any one that performs pattern matching, and can be configured as a laser processing apparatus that applies laser processing to the wafer 4 or various processing apparatuses that apply various kinds of processing inclusive of examination to the wafer 4.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing apparatus for processing a wafer formed on a front surface thereof with a plurality of devices in a state of being partitioned by a plurality of intersecting streets, the processing apparatus comprising:
a chuck table that holds the wafer;
a processing unit that processes the wafer held by the chuck table;
a processing feeding mechanism that puts the chuck table and the processing unit into relative processing feeding;
an imaging unit that images the wafer held by the chuck table to detect a region to be processed; and
a control unit, wherein
the imaging unit includes a microscope and an imaging element connected to the microscope and including a plurality of pixels that capture an image,
the control unit has a target pattern storage section that stores a target pattern for performing pattern matching and a rectilinear region detection section that detects a rectilinear region on a basis of an image from the imaging element, and
a deviation angle between a direction of the rectilinear region detected by the rectilinear region detection section and a processing feeding direction is calculated, and a relative angle between the target pattern stored in the target pattern storage section and a characteristic pattern on the wafer is adjusted, to perform the pattern matching.

2. The processing apparatus according to claim 1, wherein the control unit rotates the chuck table by the deviation angle to adjust the relative angle.

3. The processing apparatus according to claim 1, wherein the control unit rotates the target pattern stored in the target pattern storage section by the deviation angle through image processing to adjust the relative angle.
